(19) United States
(12) Patent Application Publication
(10) Pub. No.: US 2010/0270533 A1
(43) Pub. Date: Oct. 28, 2010

(54) ZnO-BASED SEMICONDUCTOR ELEMENT

(75) Inventors: Ken Nakahara, Kyoto (JP); Hiroyuki Yuji, Kyoto (JP); Masashi Kawasaki, Miyagi (JP); Akira Ohtomo, Miyagi (JP); Atsushi Tsukazaki, Miyagi (JP)

Correspondence Address: RABIN & Berdo, PC, 1101 14TH STREET, NW, SUITE 500, WASHINGTON, DC, 20005, US

(73) Assignee: ROHM CO., LTD., Kyoto (JP)

(21) Appl. No.: 12/733,440

(22) PCT Filed: Sep. 5, 2008
(86) PCT No.: PCT/JP2008/066061

§ 371 Date: Jul. 2, 2010

(30) Foreign Application Priority Data
Sep. 7, 2007 (JP) 2007-233018

(51) Int. Cl. H01L 29/15; H01L 29/22

(52) U.S. Cl. 257/14; 257/43; 257/E29.094; 257/E29.072; 977/755

(57) ABSTRACT

Provided is a ZnO-based semiconductor device capable of achieving easier conversion into p-type by alleviating the self-compensation effect and by preventing donor impurities from mixing in. The ZnO-based semiconductor device includes a MgₓZn₁₋ₓO substrate (0≦x≦1) having such a principal surface that: a projection axis obtained by projecting a normal line to the principal surface onto a plane formed by an a-axis and a c-axis of substrate crystal axes is inclined towards the a-axis by an angle of φₐ degrees; a projection axis obtained by projecting the normal line to the principal surface onto a plane formed by an m-axis and the c-axis of the substrate crystal axes is inclined towards the m-axis by an angle of Φₘ degrees; the angle Φₐ satisfies 70≦{90−(180/π)arctan(tan(πΦₐ/180)/tan(πΦₘ/180))≦110; and the angle Φₘ≧1. Accordingly, a ZnO-based semiconductor layer formed on the principal surface can be easily converted into p-type because the donor impurities are prevented from mixing in and the self-compensation effect is alleviated. Thus, the desired ZnO-based semiconductor device can be fabricated.

### TECHNICAL FIELD

The invention relates to a ZnO-based semiconductor device made of ZnO-based semiconductor materials such as ZnO and MgZnO.

### BACKGROUND ART

Studies have been made on application of devices made of ZnO-based semiconductor materials, which is a type of oxide, to an ultraviolet LED used as a light source for illumination, backlight or the like, a high-speed electronic device, a surface acoustic wave device, and so forth. ZnO has drawn attention to its versatility, large light emission potential and the like. However, no industrial development was made on ZnO as a semiconductor device material. The largest obstacle is that p-type ZnO cannot be obtained because of difficulty in acceptor doping. Nevertheless, as demonstrated by Non-patent Documents 1 and 2, technological progress of recent years has made it possible to produce p-type ZnO, and has proven that light is emitted from the p-type ZnO. Accordingly, active research on ZnO is underway.

A proposal has been made on use of nitrogen as an acceptor for obtaining p-type ZnO. As disclosed in Non-patent Document 3, when ZnO is doped with nitrogen as an acceptor, the temperature of the substrate needs to be lowered because the efficiency of nitrogen doping heavily depends on a growth temperature. However, the lowering of the substrate temperature degrades crystallinity and forms a carrier compensation center that compensates the acceptor, and thus nitrogen is not activated (self-compensation effect). This self-compensation effect makes the formation of a p-type ZnO layer, itself, extremely difficult.

To address this issue, Non-patent Document 2 describes a method of forming of a p-type ZnO-based semiconductor layer with a high-carrier concentration. According to the method, −C plane is used as a principal surface of the growth, and the growth temperature is modulated so as to repeatedly rise and fall between 400° C. and 1000° C. by taking advantage of the temperature dependency of the nitrogen-doping efficiency.

Patent Document 1: Japanese Patent Application Publication No. Hei 7-14765

### Non-patent Document 1: A. Tsukazaki et al., JJAP 44 (2005) L643

### Non-patent Document 2: A. Tsukazaki et al., Nature Material 4 (2005) 42

### Non-patent Document 3: K. Nakahara et al, Journal of Crystal Growth 237-239 (2002) p. 503

### DISCLOSURE OF THE INVENTION

### Problems to be Solved by the Invention

However, this method involves the following problems. The continuous process of heating and cooling results in the alternate repetition of thermal expansion and contraction of the manufacturing machine. This imposes heavy burden on the manufacturing machine. For this reason, the manufacturing machine requires an extensive configuration, and periodic maintenance service at shorter intervals. Furthermore, the method requires the temperature to be accurately controlled because the doping amount is determined by a part of the process at the lower temperature. However, it is difficult, to control the temperature so that the temperature will reach 400° C. and 1000° C. accurately in a short time period, and the reproducibility and stability of the doping thus become inadequate. Further, since the method uses a laser as a heating source, the method is not suitable for heating a large area. In addition, it is difficult to perform multiple semiconductor growth, although the growth of multiple semiconductor films is needed to reduce device manufacturing costs.

In the fabrication of a ZnO thin film, a radical generator is used as an apparatus to supply a gas element when oxygen is supplied, or when nitrogen is doped for obtaining a p-type ZnO.

A radical generator (radical cell) includes a hollow discharge tube, a high-frequency coil wound around the outer circumference of the discharge tube, and the like. When a high-frequency voltage is applied to the high-frequency coil, the gas introduced into the discharge tube is turned to plasma and is discharged (see Patent Document 1, for example).

The plasma contains are, however, high-energy particles, so that sputtering phenomenon is caused by the plasma particles. The inner wall of the discharge tube is always sputtered by the plasma particles, and the atoms forming the discharge tube are struck out and mixed into the plasma.

In the case of an oxide such as a ZnO-based thin film, because the gas component is oxygen, the material often used for the discharge tube in the radical cell is not a material that will be decayed by the oxidation, such as pBN, but is quartz. Quartz is used because, for the time being, it is not easy to obtain a insulating material that is as highly pure as quarts. Even in the case of quartz, however, the plasma sputters Si, Al, B, and the like, which form parts of the discharge tube.

In particular, the amount of emitting Si, which is the main element included in quartz, is large. The emitting Si is supplied directly onto the surface of a growth substrate from a discharging opening of the discharge tube together with the raw-material gas, and is taken into the MgZnO thin film. It is easy to imagine that the Si thus taken into MgZnO occupies the site of Zn. The Si thus occupying the Zn site functions as a donor, and makes it more difficult to achieve the conversion into p-type.

The invention has been made to solve the above-described problems, and an object of the invention is to provide a ZnO-based semiconductor device capable of achieving easier conversion into p-type by alleviating the self-compensation effect and by preventing donor impurities from mixing in.

### Means for Solving the Problems

To achieve the above object, the invention according to claim 1 is a ZnO-based semiconductor device including: an MgₓZn₁₋ₓO substrate (0≦x≦1) having a principal surface including a C plane; and a ZnO-based semiconductor layer formed on the principal surface, wherein a projection axis obtained by projecting a normal line to the principal surface onto a plane formed by an a-axis and a c-axis of substrate crystal axes is inclined towards the a-axis by an angle of Φₐ degrees, a projection axis obtained by projecting the normal line to the principal surface onto a plane formed by an m-axis and the c-axis of the substrate crystal axes is inclined towards the m-axis by an angle of Φₘ degrees, the angle Φₐ satisfies 70≦{90−(180/π)arctan(tan(πΦₐ/180)/tan(πΦₘ/180))}≦110, and the angle Φₘ≧1.

The invention according to claim 2 is the ZnO-based semiconductor device according to claim 1, wherein the C plane is a +C plane.

The invention according to claim 3 is a ZnO-based semiconductor device including: an MgₓZn₁₋ₓO substrate (0≦x≦1) having a principal surface including a C plane; and a ZnO-based semiconductor layer formed on the principal surface and including a p-type Mg_{y}Zn_{1-y}O layer (0≦y≦1), wherein a normal direction to the principal surface is inclined from a c-axis mainly towards an m-axis by an angle ranging from 1° to 15°, inclusive.

The invention according to claim 4 is the ZnO-based semiconductor device according to claim 3, wherein the normal direction to the principal surface is inclined from the c-axis towards the m-axis by an angle ranging from 1.5° to 15°, inclusive.

The invention according to claim 5 is the ZnO-based semiconductor device according to claim 3, wherein the ZnO-based semiconductor layer is a laminate including an active layer and the p-type Mg_{y}Zn_{1-y}O layer that is formed on the active layer.

The invention according to claim 6 is the ZnO-based semiconductor device according to claim 5, wherein the active layer has any of a monolayer structure including a single ZnO layer and a multiple quantum well structure including ZnO layers and MgZnO layers formed alternately.

### EFFECTS OF THE INVENTION

A ZnO-based semiconductor device of the invention is formed so that a projection axis obtained by projecting a normal line to a principal surface of a MgₓZn₁₋ₓO substrate (0≦x≦1) onto a plane formed by an a-axis and a c-axis of substrate crystal axes is inclined towards the a-axis by an angle of Φₐ degrees, and a projection axis obtained by projecting the normal line to the principal surface onto a plane formed by an m-axis and the c-axis of the substrate crystal axes is inclined towards the m-axis by an angle of Φₘ degrees. In addition, the angle Φₐ satisfies the relationship: 70≦{90−(180/π)arctan(tan(πφₐ/180)/tan(πφₘ/180))}≦110, and at the same time, the angle φₘ≧1. Accordingly, a ZnO-based semiconductor layer, formed on the principal surface can activate the acceptor impurities by keeping flatness, by preventing the donor impurities from mixing in, and by alleviating the self-compensation effect. Thus, the desired ZnO-based semiconductor device can be fabricated easily.

### BRIEF DESCRIPTION OF THE DRAWINGS

FIG. 1 is a chart showing the results of PL measurement performed by changing the off angle of the principal surface of ZnO substrate in the m-axis direction while the ZnO substrate has a structure shown in FIG. 10.

FIG. 2 shows diagrams each showing a film surface formed on an MgₓZn₁₋ₓO substrate of a case where the principal surface of the substrate has an off angle in the m-axis direction.

FIG. 3 is a chart illustrating the relationship between the concentrations of the mixed-in donor impurities and the off angle of the principal surface of the ZnO substrate with respect to the m-axis direction.

FIG. 4 shows diagrams illustrating surfaces of a ZnO substrate of a case where a line Z normal to the substrate principal surface has an off angle only in the m-axis direction.

FIG. 5 is a diagram illustrating the relationship of a line normal to a substrate principal surface with the substrate crystal axes, which are c-axis, m-axis, and a-axis.

FIG. 6 shows diagrams illustrating the inclination of the normal line to the principal surface of the substrate and the relationship between step edges and m-axis.

FIG. 7 shows diagrams illustrating the surface states of MgₓZn₁₋ₓO substrates that differ from one another in the off angle, in the a-axis direction, of the normal line to the principal surface of the substrate.

FIG. 8 is a schematic diagram illustrating the mechanism of the DAP luminescence

FIG. 9 is a diagram illustrating an example ZnO-based semiconductor device made by use of an MgₓZn₁₋ₓO substrate having an off angle.

FIG. 10 is a diagram illustrating a basic structure of a case where a ZnO-based thin film is formed.

FIG. 11 is a graph illustrating the association between the surface flatness of a nitrogen-doped MgZnO thin film and the concentration of mixed-in Si.

FIG. 12 is a graph illustrating the association between the surface flatness of a nitrogen-doped MgZnO thin film and the concentration of mixed-in Si.

### DESCRIPTION OF SYMBOLS

1 ZnO substrate
2 p-type MgZnO layer

### BEST MODES FOR CARRYING OUT THE INVENTION

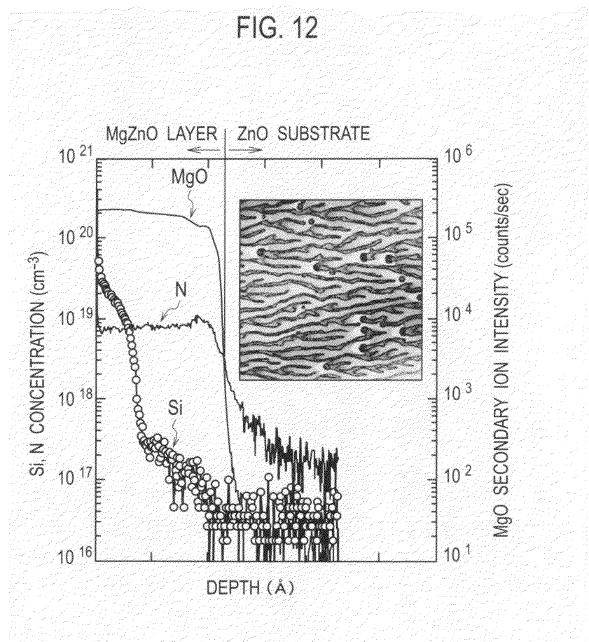

Firstly, the inventors have found that even if the ZnO-based thin film is formed by crystal growth using a radical cell or the like, a flatter surface of the ZnO-based thin film helps to exclude unintended impurities such as Si. Japanese Patent Application No. 2007-221198, which has been already filed, describes the finding. FIGS. 11 and 12, which are part of the description of Japanese Patent Application No. 2007-221198, show that the surface flatness makes a difference in the mixing of impurities such as Si. Note that, the term ZnO-based in ZnO-based thin film or in ZnO-based semiconductor layer refers to the fact that the material is a mixed crystal material having ZnO as a base and substituting either a IIA-group substance or a IIB-group substance for a part of Zn, or substituting a VIB-group substance for a part of O, or including the combination of both. Here, an MgZnO thin film will be taken as an example.

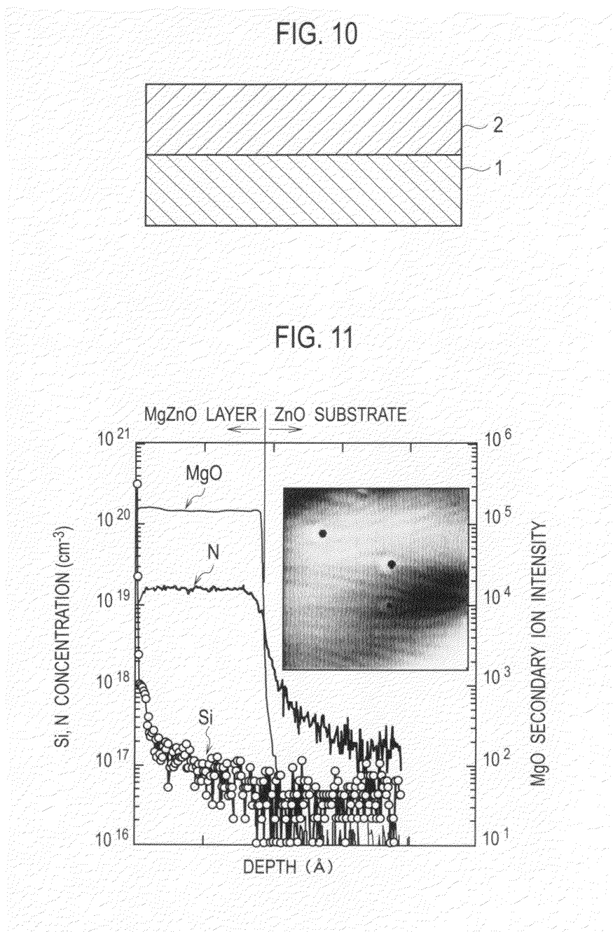

In particular, Si is one of the elements included in the discharge tube of the radical cell, and is the substance that is mixed in the most. So, Si is taken as an example for the following description. FIGS. 11 and 12 show the association between the surface flatness of the MgₓZn₁₋ₓO thin film (0≦x≦1) and the concentration of the mixed-in Si. To investigate the association, a nitrogen-doped MgZnO layer 2 was formed on a ZnO substrate 1, as FIG. 10 shows, by epitaxial growth performed in an MBE (molecular beam epitaxy) apparatus having a radical cell. The images superposed on the graphs in FIGS. 11 and 12 were obtained by scanning a 20-μm square area of the surface of the nitrogen-doped MgZnO layer 2 by use of an atomic force microscope (AFM). In addition, the silicon concentration and the nitrogen concentration in the MgZnO layer 2 were measured quantitatively by the secondary ion mass spectroscopy (SIMS).

In each of FIGS. 11 and 12, the vertical axis on the left-hand side represents either the Si concentration or the N concentration whereas the vertical axis on the right-hand side represents the secondary ion intensity of MgO. The images superposed on the graphs represent the surface states of the MgZnO layer 2. The region where the secondary ion intensity of MgO appears corresponds to the MgZnO layer 2 whereas the region where the secondary ion intensity of MgO is almost as low as zero corresponds to the ZnO substrate.

The images superposed in the graphs show that the surface flatness of the MgZnO thin film is better in FIG. 11. The concentration of Si mixed in the thin film is higher in FIG. 12, whose MgZnO thin film has a less flat surface (a coarser surface).

The flatness of the ZnO-based thin film formed on the ZnO substrate 1 depends on the off angle formed by the normal direction to the crystal-growth-side surface of the ZnO substrate 1 and the c-axis, which is one of the substrate crystal axes. What follows is a description of this dependency.

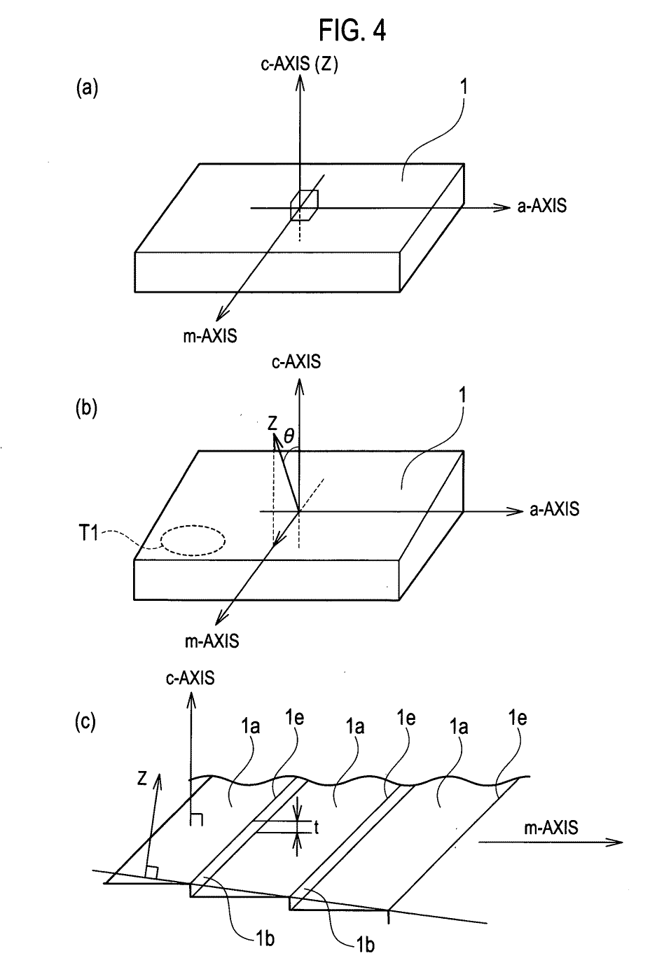

Like GaN, ZnO-based compounds have a hexagonal crystal structure known as the Wurtzite structure. The terms such as the “C plane” and the “a-axis” can be expressed by Miller indices. For example, the C plane is expressed as {0001} plane. When a ZnO-based thin film is made to grow on a ZnO-based material layer, the growth is usually performed on the C plane, that is, the {0001} plane. If a C-plane just substrate is used, the normal direction Z to the wafer's principal surface coincides with the c-axis direction as FIG. 4(a) shows. It is a well-known fact that even if a ZnO-based thin film is made to grow on a C-plane just ZnO substrate, no improvement can be achieved in the flatness of the film. In addition, in a bulk crystal wafer, the normal direction to the wafer's principal surface does not coincide with the c-axis direction unless a cleavage plane that the crystal has is used. In addition, the use of only the C-plane just substrate results in lower productivity.

Accordingly, the normal direction to the principal surface of the ZnO substrate (wafer) 1 is made not to coincide with the c-axis direction. That is, the normal direction Z is inclined from the c-axis of the principal surface of the wafer, so that an off angle is formed between the normal direction Z and the c-axis. As FIG. 4(b) shows, if the normal line Z to the principal surface of the substrate is inclined from the c-axis towards only the m-axis by 0 degrees, for example, terrace surfaces 1a and step surfaces 1b shown in FIG. 4(c), which is an enlarged view of the surface portion (e.g., of an area T1) of the substrate 1. Each of the terrace surfaces 1a is a flat surface. Each of the step surfaces is formed at the portion where there is a level difference caused by the inclination. The step surfaces 1b are arranged equidistantly and regularly.

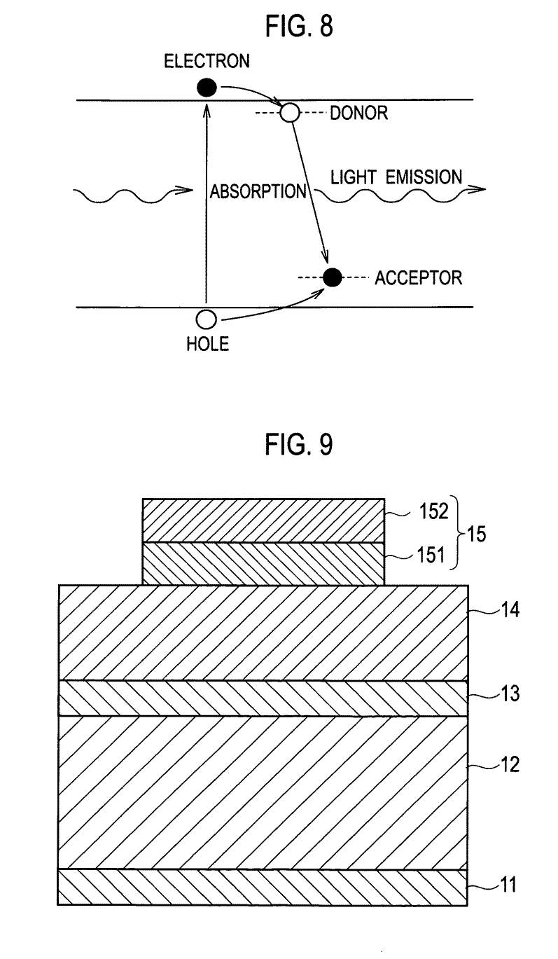

Note that each terrace surface 1a corresponds to the C plane {0001} whereas each step surface 1b corresponds to the M plane {10-10}. As FIG. 8(c) shows, the step surfaces 1b thus formed are arranged in the m-axis direction at regular intervals with the widths of the terrace surfaces 1a maintained equal to each other. As FIG. 4(c) shows, the c-axis, which is perpendicular to the terrace surfaces 1a, is inclined from the Z axis by θ°. Step lines 1e, which are the step edges of the step surfaces 1b, are arranged in parallel with each other at intervals each equal to the width of the terrace surface 1a, while maintaining a perpendicular relationship with the m-axis direction.

In this way, if the step surfaces are formed as surfaces corresponding to the M planes, a ZnO-based semiconductor layer formed by crystal growth on a principal surface can be made as a flat film. Although level-difference portions are formed in the principal surface by the step surfaces 1b, each of the flying atoms that come to these level-difference portions is bonded to the two surfaces, that is, one of the terrace surfaces 1a and a corresponding one of the step surfaces 1b. Accordingly, such atoms can be bonded more strongly than the flying atoms that come to the terrace surfaces 1a. Consequently, the flying atoms can be trapped stably by the level-difference portions.

In a surface diffusion process, the flying atoms are diffused within each terrace. Such atoms are trapped at the level-difference portions where the bonding force is stronger or at kink positions that are formed in the level-difference portions. The trapped atoms are taken into the crystal. The kind of crystal growth that progresses in this way is known as a lateral growth, and is a stable growth. Accordingly, if a ZnO-based semiconductor layer is laminated on a substrate with the normal line to the principal surface of the substrate inclined at least in the m-axis direction, the crystal of the ZnO-based semiconductor layer grow around the step surfaces 1b. Consequently, a flat film can be formed.

To put it differently, what are necessary for the fabrication of a flat film is the step lines 1e which are arranged regularly in the m-axis direction and which have a perpendicular relationship with the m-axis direction. In contrast, if the intervals and the lines of the step lines 1e are improper, the lateral growth described above cannot progress. Consequently, no flat film can be fabricated.

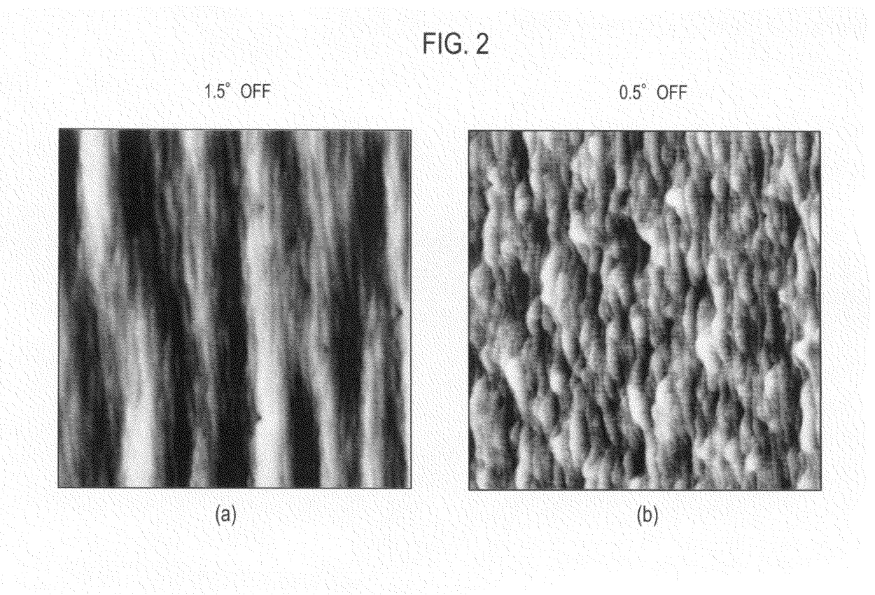

FIGS. 2(a) and 2(b) shows how the inclination angle in the m-axis direction affects the flatness of the resultant grown film. FIG. 2(a) shows the surface of a nitrogen-doped MgZnO thin film made to grow, as FIG. 10 shows, on a principal surface of a ZnO substrate having an off angle equal to a 1.5° inclination angle θ. FIG. 2(b) shows the surface of a nitrogen-doped MgZnO thin film made to grow, as FIG. 10 shows, on a principal surface of a ZnO substrate having an off angle equal to a 0.5° inclination angle θ. Each of FIGS. 2(a) and 2(b) is obtained by scanning a 2-μm square area of their respective surfaces by use of an AFM after the crystal growth. The image of FIG. 2(a) shows that the widths of the steps are arranged regularly and that the film thus formed is fine. The image of FIG. 2(b) shows that irregularities are found from place to place and that the film thus formed loses flatness. Accordingly, for the purpose of achieving certain flatness of a nitrogen-doped film, the inclination angle θ is preferably equal to or larger than 1°. In addition, a similar fact can be proved concerning the inclination angle Φₘ. So, the angle Φₘ is preferably equal to or larger than 1°.

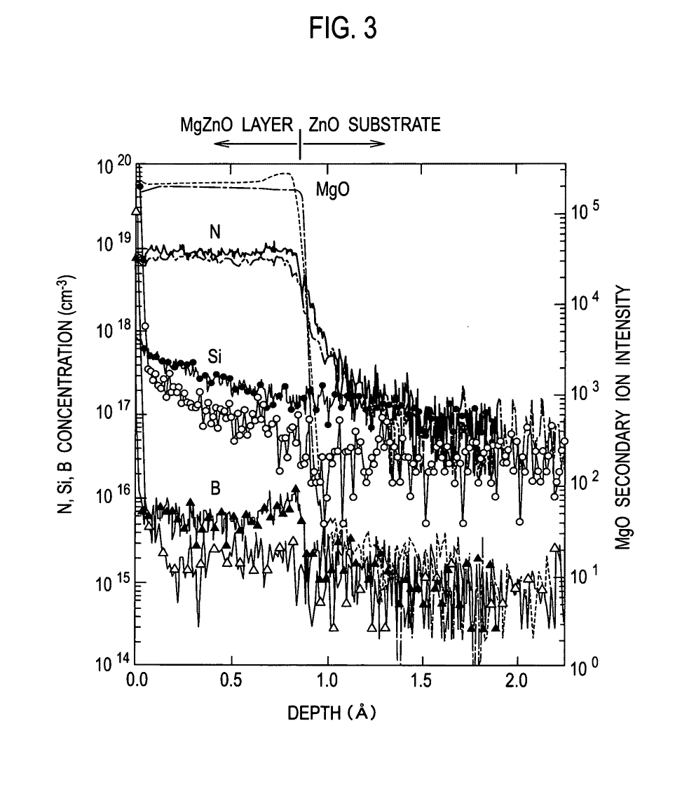

As FIG. 2 shows, the nitrogen-doped MgZnO thin film formed with a larger off angle has a better surface flatness than the surface flatness of the nitrogen-doped MgZnO thin film formed with a smaller off angle. What will be described next by referring to FIG. 3 is the relationship between the off angle of the normal line to the principal surface of the ZnO substrate with respect to the c-axis and each of the concentrations of: nitrogen doped into a nitrogen-doped MgZnO thin film formed on a principal surface of a ZnO substrate; the mixed-in silicon Si and the mixed-in boron B. To investigate the relationship, a nitrogen-doped, p-type MgZnO layer 2 was formed on a ZnO substrate 1, as FIG. 10 shows, by epitaxial growth performed in a molecular beam epitaxy (MBE) apparatus having a radical cell. The silicon concentration, the boron concentration, and the nitrogen concentration in the MgZnO layer 2 were measured by the secondary ion mass spectroscopy (SIMS).

In FIG. 3 the vertical axis on the left-hand side represents each of the nitrogen (N) concentration, the silicon (Si) concentration, and the boron (B) concentration. The vertical axis on the right-hand side represents the secondary ion intensity of MgO. The horizontal axis represents the depth or the film thickness (in angstrom Å). The region where the secondary ion intensity of MgO appears corresponds to the MgZnO layer whereas the region where the secondary ion intensity of MgO is almost as low as zero corresponds to the ZnO substrate. Each of the N-concentration, the Si-concentration, the B-concentration, and the secondary intensity of MgO is represented by two curves in FIG. 3 so as to be compared with each other. Curves in each pair represent, respectively, the cases of two different off angles θ, namely 1.5° and 0.5°, of the normal line to the principal surface of the ZnO substrate with respect to the c-axis, which are determined so as to correspond to FIGS. 2(a) and 2(b).

Of the two curves of the boron (B) concentration, the one represented by the data of white triangles (Δ) is of the case where the inclination angle (off angle) θ is 1.5° (corresponding to FIG. 2(a)), and the one represented by the data of black triangles (▴) is of the case where the inclination angle θ is 0.5°. Of the two curves of the silicon (Si) concentration, the one represented by the data of white circles (∘) is of the case where the inclination angle θ is 1.5°, and the one represented by the data of black circles () is of the case where the inclination angle θ is 0.5°. Of the two curves of the nitrogen (N) concentration, the one represented by the data of the double-dot chain line is of the case where the inclination angle θ is 1.5°, and the one represented by the data of the solid line is of the case where the inclination angle θ is 0.5°. Of the two curves of the magnesium oxide (MgO) concentration, the one represented by the data of the dotted chain line is of the case where the inclination angle θ is 1.5°, and the one represented by the data of the alternate dot-and-chain line is of the case where the inclination angle θ is 0.5°.

As FIG. 3 shows, the amount of doped nitrogen of the case of the smaller off angle (θ=0.5° changes little in comparison to the corresponding amount of the case of the larger off angle (θ=1.5°. In addition, the concentrations of the mixed-in donor impurities, such as Si and B, are lower in the cases of the smaller off angle (θ=0.5° than in the cases of the larger off angle (θ=1.5°. The lowering of the concentrations of the mixed-in donor impurities, such as Si and B, is because of the above-described fact that the better the flatness of the film is, the better the mixing of the donor impurities can be prevented. Almost no changes observed in the amount of doped nitrogen may be because of the following reason.

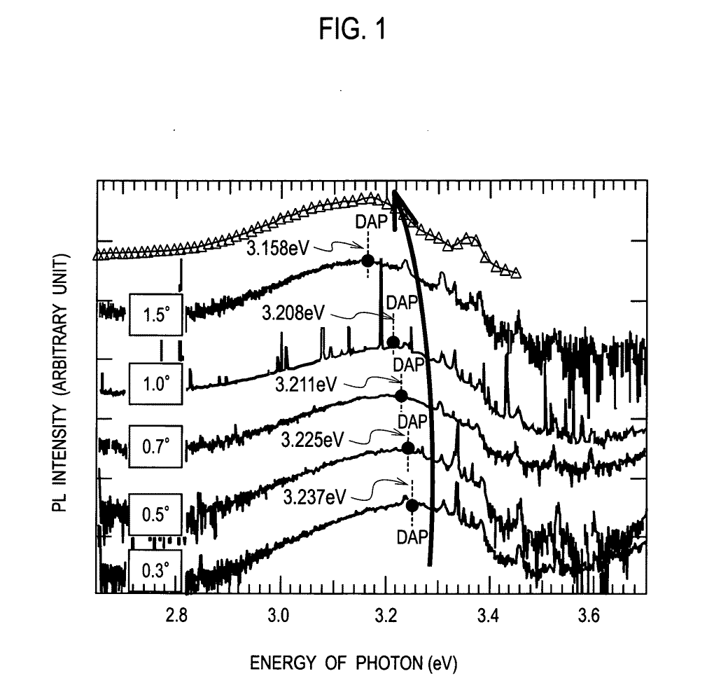

FIG. 1 shows the result of photoluminescence (PL) of various ZnO-based laminates, shown in FIG. 10, cooled at 12 K (Kelvin) and excited by a He—Cd laser. Each of the ZnO-based laminates was prepared by growing a nitrogen-doped MgZnO thin film on a principal surface of a ZnO substrate having an off angle, as FIG. 10 shows. The horizontal axis of FIG. 1 represents the energy of photon (eV) whereas the vertical axis is in an arbitrary unit (of logarithmic scale) commonly used at PL measurements. The amount of doped nitrogen was set at 2×10²⁰ cm⁻³, and the off angle of the principal surface of the ZnO substrate was varied at five steps—specifically, 0.3°, 0.5°, 0.7°, 1.0°, and 1.5°. The photoluminescence measurement on the ZnO-based laminate was performed for each of the cases of the five steps. The numbers put on the left-hand side of FIG. 1 represents, respectively, the five off angles.

When the acceptors are doped, a commonly-observable phenomenon, donor-acceptor pair (DAP) luminescence can be observed clearly. FIG. 8 is a schematic diagram illustrating the mechanism of the DAP luminescence. The position of the DAP luminescence is determined as follows.

When E_{DAP} is the energy of DAP luminescence, E_{G} is the minimum excitation energy, E_{D} is the donor level, E_{A} is the acceptor level, r_{DA} is the distance between the donor and the acceptor, ε₀ is the vacuum permittivity, εᵣ is the relative permittivity, e is the charges of electrons, h is the Planck's constant, and ω_{LO} is the LO (longitudinal-optical) phonon frequency, then

E_{DAP}=E_{G}−E_{D}−E_{A}+(e²/4πε₀εᵣr_{DA})−(mhω_{LO}/2π).

Here, m is an integer that is equal to or larger than zero.

The DAP luminescence peak position is determined by the equation above. So, given kinds of the donor and of the acceptor and their respective concentrations, the DAP luminescence peak position is determined.

As the off angle becomes larger, the DAP-luminescence peak position shifts towards the lower-energy side (such shifting is often referred to as “deepening”). The values of the energy put in FIG. 1 represents, respectively, the positions of the DAP luminescence. When the off angle of the principal surface of the ZnO substrate is 0.3°, the position of the DAP luminescence is at 3.237 eV. As the off angle changes from 0.5° to 0.7°, and then to 1.0°, the position of the DAP luminescence changes to the deeper ones—specifically, from 3.225 eV to 3.221 eV, and then to 3.208 eV.

In the case of ZnSe, it is a known fact that a deeper DAP-luminescence position has an advantageous effect on the conversion to p-type. Thus, a deeper DAP luminescence position is more preferable. When acceptors are doped, compensatory donors are always formed (self-compensation effect). The II-VI group substances have a higher self-compensation effect than the III-V group substances. Accordingly, if the compensatory donors have shallow levels, electrons are supplied so as to be re-combined with the holes released from the acceptors. Deeper compensatory donors are less likely to release electrons, so that the holes can be more observable. In FIG. 1, as the off angle changes from 1° to 1.5°, the position of the DAP luminescence moves, or deepens, by a larger magnitude than in the cases of the shifting of the DAP-luminescence positions caused by the changes among the smaller off-angles. This means that a large off angle, such as one that is equal to or larger than 1° or more preferably 1.5°, alleviates the self-compensation effect, and, therefore, has an advantageous effect on p-type conversion.

The ZnO-based laminates, as shown in FIG. 10, used in the aforementioned various measurements were fabricated as follows. ZnO substrates each having the +C plane as its principal surface and each having an off angle in the m-axis direction were used. The principal surface of each ZnO substrate was etched with hydrochloric acid, then was washed with pure water, and then was dried with dry nitrogen. Subsequently, the resultant ZnO substrate was set in a holder, and was placed in an MBE apparatus through a load lock. The ZnO substrate was then heated at 900° C. for 30 minutes in a vacuum of approximately 1×10⁻⁷ Pa. Then, the temperature of the substrate was lowered down to 800° C., and NO gas and O₂ gas were supplied to a plasma tube to produce plasma. The plasma thus produced was supplied, together with Mg and Zn that have been adjusted so as to have desired compositions, and thus the nitrogen-doped MgZnO was fabricated. As the result of a CV measurement performed on the MOS types having SiO2 formed on ZnO, with the amount of doped nitrogen being approximately 5×10¹⁸ cm⁻³, the excessive acceptor concentration defined as “NA (acceptor concentration)—ND (donor concentration)” was 1×10¹⁶ cm⁻³ when the off angle was 0.5°, and the excessive acceptor concentration ranged from 6×10¹⁶ cm⁻³ to 7×10¹⁶ cm⁻³ when the off angle was 1.5°. The higher off angle resulted in a higher excessive acceptor concentration.

Accordingly, to alleviate the self-compensation effect and to prevent the mixing of the donor impurities, it is preferable that the normal direction Z to the principal surface of the substrate be allowed to be inclined from the c-axis towards only the m-axis with an inclination angle that is equal to or larger than 1°, or more preferably 1.5°. If, however, the normal direction Z to the principal surface of the substrate has too large an off angle, the effective volume of the bulk crystal becomes smaller. The “effective volume” refers to the volume of the bulk crystal that can be used for cutting out wafers of a predetermined size from the bulk crystal. If the effective volume is too small, the bulk crystal is not adequate for mass production of wafers. Accordingly, in practice, the inclination angle θ of the normal direction Z is approximately 15° at most.

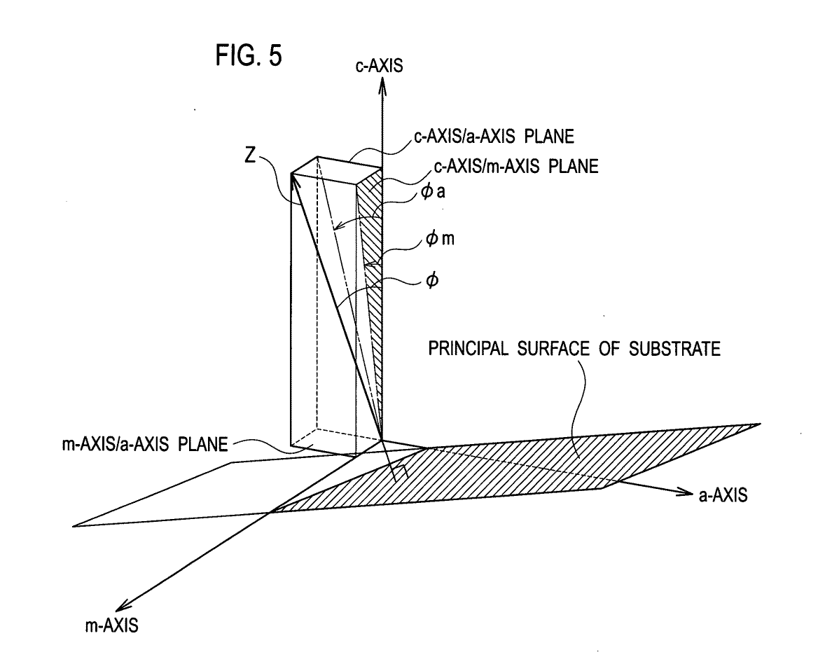

The foregoing description is based on an assumption that the normal direction Z to the principal surface of the substrate is inclined from the c-axis towards only the m-axis. In practice, however, it is difficult to cut out wafers with the normal direction Z to the principal surface of the substrate inclined from the c-axis towards only the m-axis. As a production technique, it is necessary to allow the normal direction Z to the principal surface of the substrate to be inclined from the c-axis towards the a-axis too, and also necessary to set the maximum allowable inclination angle towards the a-axis. Accordingly, the following description is based on an example as shown in FIG. 5. The normal line Z to the principal surface of the substrate is inclined from the c-axis of the substrate crystal axes at an angle Φ. The projected axis obtained by projecting the normal line Z onto the c-axis/m-axis plane within the Cartesian coordinate system of the c-axis, the m-axis, and the a-axis of the substrate crystal axes is inclined towards the m-axis at an angle Φₘ. The projection axis obtained by projecting the normal line Z onto the c-axis/a-axis plane is inclined towards the a-axis at an angle Φₐ.

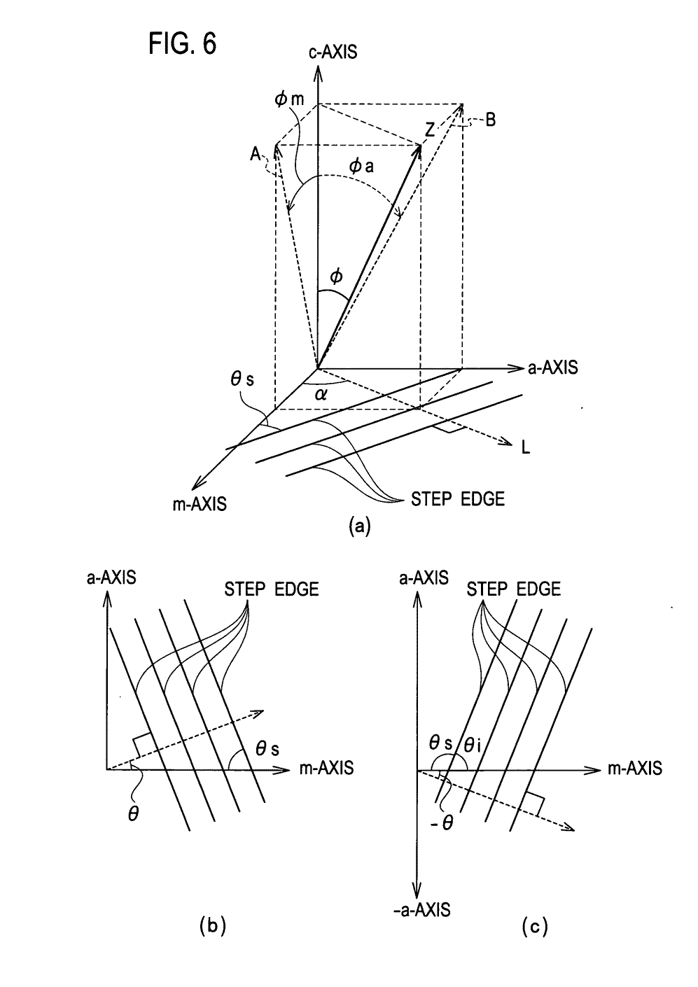

The normal line Z to the principal surface is inclined as shown in FIG. 5, and the inclined state is described in a more understandable manner in FIG. 6(a). In FIG. 6(a), the relationship between the normal line Z and the Cartesian coordinate system of the c-axis, the m-axis, and the a-axis is described. FIG. 6(a) differs from FIG. 5 only in the inclination direction of the normal line Z to the principal surface of the substrate. The symbols Φ, Φₘ, and Φₐ. mean the same as their respective counterparts in FIG. 5. In FIG. 6(a), the projection axis A is an axis obtained by projecting the normal line Z to the principal surface of the substrate onto the c-axis/m-axis plane within the Cartesian coordinate system of the c-axis, the m-axis, and the a-axis whereas the projection axis B is an axis obtained by projecting the normal line Z onto the c-axis/a-axis plane.

In addition, in FIG. 6(a) the direction L represents the direction of the projected axis obtained by projecting the normal line Z onto the a-axis/m-axis plane within the Cartesian coordinate system of the c-axis, the m-axis, and the a-axis of the substrate crystal axes. Note that the terrace surfaces 1c and step surfaces 1d shown in FIG. 4 are formed. Each of the terrace surfaces 1c is a flat surface. Each of the step surfaces 1d is formed at the portion where there is a level difference caused by the inclination. Here, each terrace surface corresponds to the C plane (0001), but unlike the case shown in FIG. 4, the normal line Z is inclined, by an angle of Φ, from the c-axis, which is perpendicular to the terrace surfaces as FIG. 6(a) shows.

Since the normal-line direction of the principal surface of the substrate is inclined not only towards the m-axis but also towards the a-axis, the step surfaces are formed obliquely so that the step surfaces are arranged in the L-direction. This state reflects a step-edge arrangement in the m-axis direction, as shown in FIGS. 6(a) and (b). Note that the M-plane is a thermally and chemically stable plane. So, if the inclination angle Φₐ in the a-axis direction is within a certain range, the obliquely-formed steps cannot be formed neatly. To put it differently, the step surfaces 1d are formed as irregular surfaces and the arrangement of the step edges is in disorder. As a result, no flat film can be formed on the principal surface. Note that the fact that the M-plane is stable both thermally and chemically was discovered by the inventors. Detailed description of this thermal and chemical stability of the M-plane is given in Japanese Patent Application No. 2006-160273, which has been already filed.

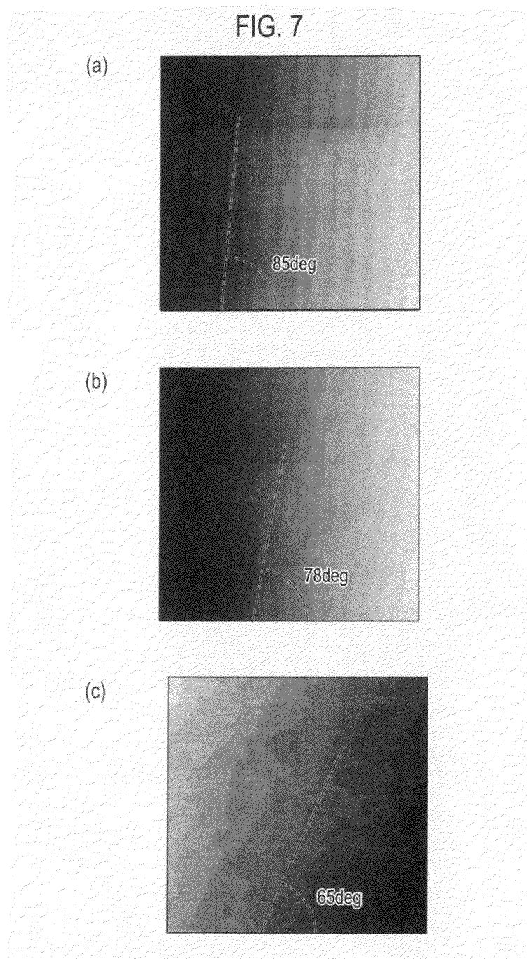

FIG. 7 shows how the step edges and the step widths change if the normal line Z to the growth surface (principal surface) has not only an off angle towards the m-axis but also an off angle towards the a axis. With an off angle Φₘ, towards the m-axis fixed to 0.4° (this off angle has been described by referring to FIG. 6(a)), the step edges and the step widths were compared as the off angle Φₐ towards the a-axis was gradually increased. In practice, the off angle Φₐ towards the a-axis was changed by changing the cut-out plane of the MgₓZn₁₋ₓO (0≦x≦1).

As the off angle Φₐ towards the a-axis increases, the angle θₛ formed by each step edge and the m-axis direction also increases. For this reason, FIG. 7 is shown with the numbers representing the angles θₛ. FIG. 7(a) shows a case of θₛ=85°. No disorder can be observed for the step edges or the step widths. FIG. 7(b) shows a case of θₛ=78°. Although slight disorder can be observed, but the step edges and the step widths are still recognizable. FIG. 7(c) shows a case of θₛ=65°. The disorder becomes worse, so that the step edges and the step widths cannot be recognized any longer. If a ZnO-based semiconductor layer is formed by epitaxial growth on a surface in the state shown in FIG. 7(c), the above-described lateral growth of the crystal is impossible. As a consequence, no flat film can be formed. If the angle θₛ is converted into the inclination angle Φₐ towards the a-axis, the case of FIG. 7(c) corresponds to a case of Φₐ=0.15. The data described above reveal that it is preferable that 70°≦θₛ≦90°.

Accordingly, when θₛ=70°, the obliquely-formed steps begin to lose their neatly-formed property, the step surfaces begin to have irregularities, and the arrangement of the step edges begin to become disorderly. For example, with an angle Φₘ=0.5, the angle θₛ=70° is converted into a 0.1° inclination angle Φₐ towards the a-axis.

When the angle θₛ is examined, a case where the projection axis B of the normal line Z to the principal surface is inclined by an angle of Φₐ in the −a-axis direction in FIG. 6(a) is equivalent, because of the symmetry, to the case where the projection axis B of the normal line Z to the principal surface is inclined by an angle of Φₐ in the a-axis direction. So, the case of the projection axis inclined in the −a-axis direction must be taken into consideration as well. FIG. 6(c) shows the lines obtained by projecting level-difference portions formed by the step surfaces onto the m-axis/a-axis plane when the projection axis B is inclined by an angle of −Φₐ. Note that a condition that is similar to the above-mentioned condition 70°≦θₛ≦90° holds true also for the angle θᵢ that is formed between each step edge and the m-axis (i.e., 70°≦θᵢ≦90°. Here, since θₛ=180°−θᵢ, the maximum value of θₛ=180°−70°=110°. Accordingly, the range 70°≦θₛ≦110° is the condition for the growth of a flat film.

Subsequently, on the basis of the drawing shown in FIG. 6, the angle θₛ is to be expressed by use of Φₘ and Φₐ. The angles to be used in the following description are in radian (rad). According to FIG. 6, an angle α is expressed as:

α=arctan(tan Φ/tan Φₘ)

Accordingly,

θₛ=(π/2)−α=(π/2)−arctan(tan Φₐ/tan Φₘ)

Converting the unit of the angle θₛ from radian to degree,

θₛ=90−(180/π)arctan(tan Φₐ/tan Φₘ)

### Accordingly,

70≦90−(180/π)arctan(tan Φₐ/tan Φₘ)≦110

As being well known, in the above formulas, tan is the abbreviation of the tangent and arctan is the abbreviation of the arctangent. Note that the case of θₛ=90° is the case where the normal line Z is not inclined towards the a-axis, but only is inclined towards the m-axis. If the angles Φₘ and Φₐ are not in radian but in degree, the inequality given above is expressed as:

70≦{90−(180/π)arctan(tan(πΦₐ/180)/tan(πΦₘ/180))}≦110

Subsequently, FIG. 9 shows an ultraviolet LED taken as an example ZnO-based semiconductor device including a ZnO-based semiconductor layer formed on a MgₓZn₁₋ₓO substrate (0≦x≦1) having an off angle within the above-mentioned range. The ZnO-based semiconductor device is formed by using the principal surface, of a ZnO substrate 12 including the +C plane as the crystal-growth surface and by making the normal direction to the principal surface inclined, by a small amount, from the c-axis towards the m-axis. On the ZnO substrate 12, an undoped ZnO layer 13 and a nitrogen-doped, p-type MgZnO layer 14 are formed by crystal growth sequentially in this order. After that, a p electrode 15 and an n electrode 11 are formed. As FIG. 9 shows, the p electrode 15 is formed as a multilayer metal film including an Au (gold) layer 152 and a Ni (nickel) layer 151. The n electrode 11 is made of 1n (indium). The nitrogen-doped MgZnO layer 14 corresponds to the ZnO-based thin film of the invention. The growth temperature is set at 800° C. so that the surface can have a favorable flatness. Various different device structures from the one shown in FIG. 9 are allowable. For example, the portion corresponding to the ZnO-based laminate shown in FIG. 9 may be replaced by a laminate including an MgZnO substrate, an undoped ZnO layer, and a nitrogen doped MgZnO layer formed in this order from below. Still alternatively, an active layer may be additionally formed so as to have a multiple quantum well (MQW) structure including alternately-formed MgZnO layers and ZnO layers.

1. A ZnO-based semiconductor device comprising:
an MgₓZn₁₋ₓO substrate (0≦x≦1) having a principal surface including a C plane; and
a ZnO-based semiconductor layer formed on the principal surface,
wherein a projection axis obtained by projecting a normal line to the principal surface onto a plane formed by an a-axis and a c-axis of substrate crystal axes is inclined towards the a-axis by an angle of Φₐ degrees,
a projection axis obtained by projecting the normal line to the principal surface onto a plane formed by an m-axis and the c-axis of the substrate crystal axes is inclined towards the m-axis by an angle of Φₘ degrees, the angle Φₐ satisfies 70≦{90−(180/π)arctan(tan(πΦₐ/180)/tan(πΦₘ/180))}≦110, and
the angle Φₘ≧1.

2. The ZnO-based semiconductor device according to claim 1, wherein the C plane is a +C plane.

3. A ZnO-based semiconductor device comprising:
an MgₓZn₁₋ₓO substrate (0≦x≦1) having a principal surface including a C plane; and
a ZnO-based semiconductor layer formed on the principal surface and including a p-type Mg_{y}Zn_{1-y}O layer (0≦y≦1),
wherein a normal direction to the principal surface is inclined from a c-axis mainly towards an m-axis by an angle ranging from 1° to 15°, inclusive.

4. The ZnO-based semiconductor device according to claim 3, wherein the normal direction to the principal surface is inclined from the c-axis towards the m-axis by an angle ranging from 1.5° to 15°, inclusive.

5. The ZnO-based semiconductor device according to claim 3, wherein the ZnO-based semiconductor layer is a laminate including an active layer and the p-type Mg_{y}Zn_{1-y}O layer that is formed on the active layer.

6. The ZnO-based semiconductor device according to claim 5, wherein the active layer has any of a monolayer structure including a single ZnO layer and a multiple quantum well structure including ZnO layers and MgZnO layers formed alternately.
